(19) United States
(12) Patent Application Publication
(10) Pub. No.: US 2026/0293077 A1
(43) Pub. Date: Sep. 24, 2026

(54) COMPONENT MOUNTING MACHINE AND CONTROL METHOD

(71) Applicant: FUJI CORPORATION, Chiryu (JP)

(72) Inventor: Kohei SUGIHARA, Nishio-shi (JP)

(73) Assignee: FUJI CORPORATION, Chiryu (JP)

(21) Appl. No.: 19/474,885

(22) PCT Filed: May 23, 2023
(86) PCT No.: PCT/JP2023/019145

§ 371 Date: Oct. 13, 2025

(51) Int. Cl. H05K 13/08; H05K 13/04

(52) U.S. Cl. CPC H05K 13/084; H05K 13/0419

(57) ABSTRACT

A component mounter includes an acquisition section to acquire, for a component supplied to a collection position of the component supply device to supply the component to be mounted on a board, component identification information from an identification member having the component identification information. The component supply device transmits a first completion notification for notifying that the component has been supplied to the collection position for an operation of acquiring the component identification information by the acquisition section or a second completion notification for notifying that the component has been supplied to the collection position for a collection operation of collecting and holding the component. The operation control section controls the operation of acquiring the component identification information by the acquisition section based on the first completion notification and the operation of collecting the component based on the second completion notification.

### TECHNICAL FIELD

The present description discloses a technique related to a component mounter and a control method.

### BACKGROUND ART

A component mounter disclosed in Patent Literature 1 includes a component supply device, a first determination section, a second determination section, and a timing setting section. The component supply device sequentially supplies components to be mounted on a board. The first determination section performs supply state determination by imaging the component before the component is collected at a collection position and determining whether a supply state of the component in the component supply device is appropriate, the first determination section performing this determination for a first component group that is a predetermined quantity of the component smaller than the number of components supplied to the board from the component supply device. The second determination section determines whether the supply state determination is necessary for a second component that is the component supplied from the component supply device after the first component is supplied, based on a result of the determination by the first determination section. The timing setting section sets an operation start timing at which a holding member that collects and holds the component to mount the component on the board starts a lowering operation for collecting the component, for both the first component and the second component.

### CITATION LIST

### Patent Literature

Patent Literature 1: WO 2020/039569

### BRIEF SUMMARY

### Technical Problem

However, in Patent Literature 1, component identification information capable of identifying the component is not taken into account. For example, a worker or a production management device can track and investigate the component supplied from the component supply device, using the component identification information. When the component mounter acquires the component identification information of the component supplied from the component supply device, it is necessary to control an operation of acquiring the component identification information and a collection operation of collecting and holding the component.

In view of such circumstances, the present description discloses a component mounter and a control method capable of controlling an operation of acquiring component identification information and an operation of collecting a component.

### Solution to Problem

The present description discloses a component mounter including an acquisition section, a component supply device, and an operation control section. The acquisition section is configured to acquire, for a component supplied to a collection position of the component supply device configured to supply the component to be mounted on a board, component identification information from an identification member having the component identification information capable of identifying the component. The component supply device is configured to transmit a first completion notification for notifying that the component has been supplied to the collection position for an operation of acquiring the component identification information by the acquisition section or a second completion notification for notifying that the component has been supplied to the collection position for a collection operation of collecting and holding the component. The operation control section is configured to control the operation of acquiring the component identification information by the acquisition section based on the first completion notification and the operation of collecting the component based on the second completion notification.

The present description further discloses a control method including an acquisition step, a notification step, and an operation control step. The acquisition step includes acquiring, for a component supplied to a collection position of a component supply device configured to supply the component to be mounted on a board, component identification information from an identification member having the component identification information capable of identifying the component. The notification step includes transmitting a first completion notification for notifying that the component has been supplied to the collection position for an operation of acquiring the component identification information by the acquisition step or a second completion notification for notifying that the component has been supplied to the collection position for a collection operation of collecting and holding the component. The operation control step includes controlling the operation of acquiring the component identification information by the acquisition step based on the first completion notification and the operation of collecting the component based on the second completion notification.

### Advantageous Effects

With the above component mounter, it is possible to appropriately control the operation of acquiring the component identification information and the operation of collecting the component. The foregoing description regarding the component mounter applies equally to the control method.

### BRIEF DESCRIPTION OF DRAWINGS

FIG. 1 is a plan view illustrating a configuration example of a component mounter.

FIG. 2 is a side view illustrating a configuration example of a mounting head.

FIG. 3 is a block diagram illustrating an example of control blocks of the component mounter.

FIG. 4 is a flowchart illustrating an example of a control procedure by the component mounter.

FIG. 5 is a plan view illustrating an example of a carrier tape.

FIG. 6 is a cross-sectional view of the carrier tape of FIG. 5.

### DESCRIPTION OF EMBODIMENTS

### 1. Embodiment

### 1-1. Configuration Example of Component Mounter 10

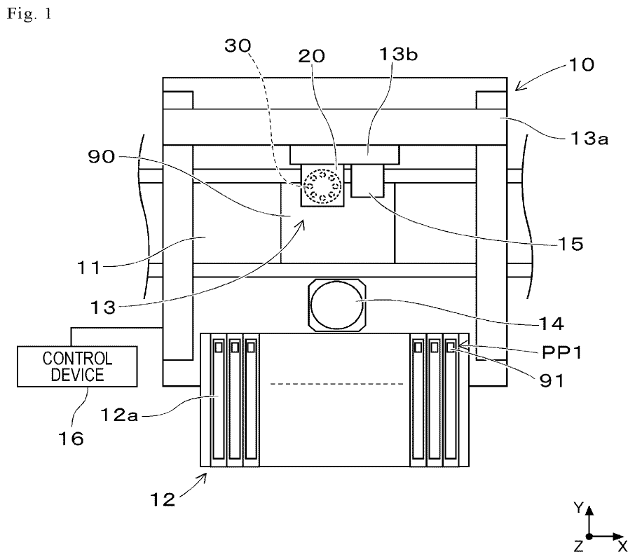

Component mounter 10 mounts component 91 on board 90. As illustrated in FIG. 1, component mounter 10 includes board conveyance device 11, component supply device 12, component transfer device 13, component camera 14, board camera 15, and control device 16.

For example, board conveyance device 11 includes a belt conveyor and the like, and conveys board 90 in a conveyance direction (X-axis direction). Board 90 is a circuit board on which an electronic circuit, an electric circuit, a magnetic circuit, or the like are formed. Board conveyance device 11 conveys board 90 into component mounter 10 and positions board 90 at a predetermined position in component mounter 10. After a process of mounting multiple components 91 by component mounter 10 ends, board conveyance device 11 conveys board 90 out of component mounter 10.

Component supply device 12 supplies components 91 to be mounted on board 90. Component supply device 12 includes multiple feeders 12a provided along the conveyance direction (X-axis direction) of board 90. Each of multiple feeders 12a is equipped with a reel. Carrier tape 80 in which components 91 are accommodated is wound around the reel. Feeder 12a pitch-feeds carrier tape 80 to supply components 91 so that component 91 can be collected at collection position PPI located on a distal end side of feeder 12a. In addition, component supply device 12 can also supply an electronic component (for example, a leaded component or the like), which is relatively larger than a chip component or the like, in a state of being arranged on a tray.

Component transfer device 13 includes head drive device 13a and moving body 13b. Head drive device 13a is configured to move moving body 13b in the X-axis direction and a Y-axis direction (a direction orthogonal to the X-axis direction on a horizontal plane) by means of a linear motion mechanism. Mounting head 20 is detachably (exchangeably) provided on moving body 13b by a clamp member. Mounting head 20 collects and holds component 91 supplied from component supply device 12 by using at least one holding member 30, and mounts component 91 on board 90 positioned by board conveyance device 11. For example, a suction nozzle, a chuck, or the like can be used as holding member 30.

Known imaging devices can be used as component camera 14 and board camera 15. Component camera 14 is fixed to a base of component mounter 10 such that an optical axis faces upward in a vertical direction (a Z-axis direction orthogonal to the X-axis direction and the Y-axis direction). Component camera 14 can image component 91, which is held by holding member 30, from below. Board camera 15 is provided on moving body 13b of component transfer device 13 such that an optical axis faces downward in the vertical direction (the Z-axis direction). Board camera 15 can capture an image of board 90 from above.

Board camera 15 can also capture an image of component 91 from above at collection position PPI of component 91. Component camera 14 and board camera 15 capture images based on a control signal transmitted from control device 16. Image data of the images captured by component camera 14 and board camera 15 is transmitted to control device 16.

Control device 16 includes a computing device and a storage device which are known, and is configured as a control circuit. Information, image data, and the like output from various sensors provided in component mounter 10 are input to control device 16. Control device 16 transmits the control signal to each device based on a control program, a predetermined mounting condition set in advance, and the like.

For example, control device 16 causes board camera 15 to capture the image of board 90 positioned by board conveyance device 11. Control device 16 performs image processing on the image captured by board camera 15 to recognize a positioning state of board 90. Moreover, control device 16 causes holding member 30 to collect and hold component 91 supplied by component supply device 12, and causes component camera 14 to capture the image of component 91 held by holding member 30. Control device 16 performs the image processing on the image captured by component camera 14 to recognize a holding posture of component 91.

Control device 16 moves holding member 30 toward a position above a planned mounting position that is set in advance by the control program or the like. Further, based on the positioning state of board 90, the holding posture of component 91, and the like, control device 16 corrects the planned mounting position and sets the mounting position on which component 91 is actually mounted. The planned mounting position and the mounting position include a rotation angle in addition to the position (X-axis coordinate and Y-axis coordinate).

Control device 16 corrects a target position (the X-axis coordinate and the Y-axis coordinate) and the rotation angle of holding member 30 in accordance with the mounting position. Control device 16 lowers holding member 30 at the corrected rotation angle at the corrected target position to mount component 91 on board 90. Control device 16 executes the mounting process of mounting multiple components 91 on board 90 by repeating the pick-and-place cycle described above. A total time of a time required for a predetermined number of cycles of the pick-and-place cycle for component 91 and a time required for the loading and unloading of board 90 corresponds to a cycle time per board 90.

### 1-2. Configuration Example of Mounting Head 20

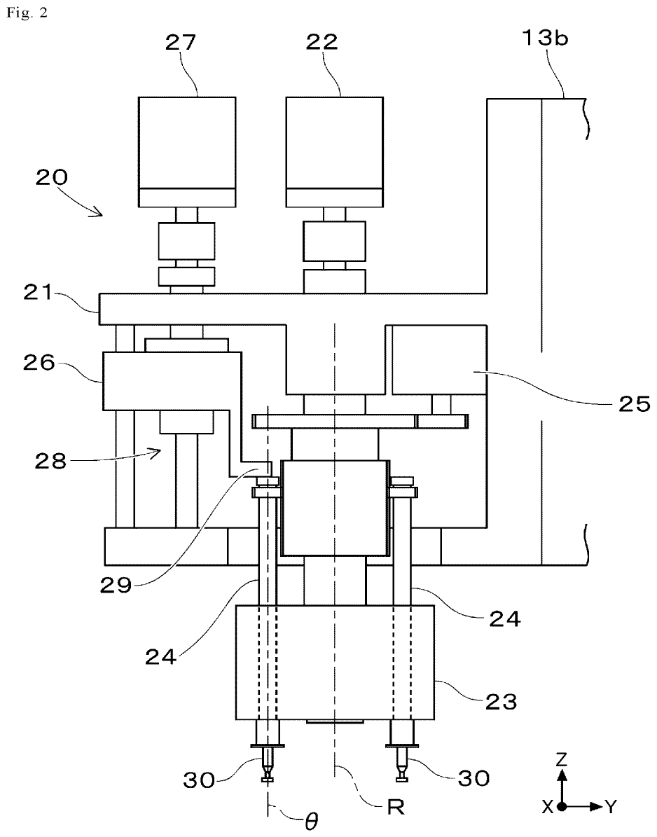

As illustrated in FIG. 2, mounting head 20 includes head main body 21 clamped by moving body 13b. Head main body 21 is provided with rotary head 23 so that the rotation angle can be indexed at predetermined angular increments by R-axis motor 22. Rotary head 23 holds multiple (for example, 24) tool shafts 24 at equal circumferential intervals on a circle concentric with the R axis, such that tool shafts 24 are slidable in the θ-axis direction parallel to the Z axis and the R axis (an up-down direction on the plane in FIG. 2) and rotatable about the θ axis.

Each of multiple tool shafts 24 is biased upward with respect to rotary head 23 by an elastic force of a spring. As a result, each tool shaft 24 is positioned at an upper end in a normal state in which no external force is applied. Holding member 30 is detachably attached to a lower end portion of each tool shaft 24. Positive-pressure air or negative-pressure air is supplied to holding member 30 to collect component 91. Holding member 30 includes a suction nozzle that picks up component 91 using negative-pressure air, a chuck that operates using positive-pressure air or negative-pressure air, and the like. In addition, when holding member 30 is attached to each tool shaft 24, holding member 30 is biased downward by an elastic force of an in-shaft spring.

Each of multiple holding members 30 holds component 91 by supplying air to an air passage of holding member 30. Multiple holding members 30 are subsequently indexed to predetermined angle positions around the R-axis (for example, lifting and lowering position of tool shaft 24) by rotating rotary head 23 as R-axis motor 22 is driven. As illustrated in FIG. 2, mounting head 20 is provided with θ-axis motor 25 fixed to head main body 21. All tool shafts 24 are connected to an output shaft of 0-axis motor 25 so that rotational force can be transmitted via multiple gears. Tool shaft 24 and holding member 30 rotate integrally (revolve) about the θ-axis by the operation of θ-axis motor 25, and the rotation angle and the rotation speed are controlled.

Further, head main body 21 is provided with actuating member 26 movable in the Z-axis direction. Actuating member 26 is lifted and lowered in the Z-axis direction by ball screw mechanism 28 that operates by the driving of Z-axis motor 27.

Actuating member 26 is provided with lever 29 that contacts an upper end portion of tool shaft 24 indexed to the lifting and lowering position of multiple tool shafts 24. Lever 29 is lowered as actuating member 26 moves downward in the Z-axis direction. Lever 29 presses tool shaft 24 downward in the Z-axis direction against the elastic force of the spring of tool shaft 24 in contact with lever 29, to lower tool shaft 24. Tool shaft 24 in contact with lever 29 and holding member 30 attached to the lower end portion of tool shaft 24 are integrally lifted and lowered in the Z-axis direction by the driving of Z-axis motor 27, and the position in the Z-axis direction, the moving speed, and the like are controlled.

### 1-3. Example of Control Related to Acquisition of Component Identification Information

For example, a worker or a production management device can track and investigate component 91 supplied from component supply device 12, using the component identification information capable of identifying component 91. When component mounter 10 acquires the component identification information of component 91 supplied from component supply device 12, it is necessary to control an operation of acquiring the component identification information and a collection operation of collecting and holding component 91. Therefore, component mounter 10 includes acquisition section 41, component supply device 12, and operation control section 42. Component mounter 10 may also include storage section 43.

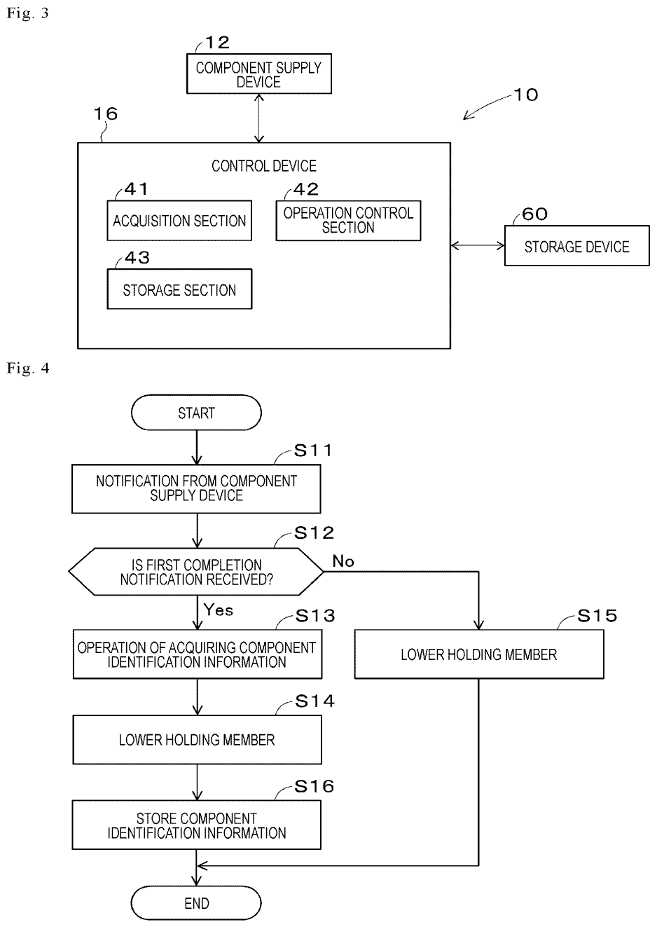

As illustrated in FIG. 3, component mounter 10 according to the embodiment includes acquisition section 41, component supply device 12, operation control section 42, and storage section 43. In addition, component mounter 10 executes control in accordance with a flowchart illustrated in FIG. 4 with respect to the operation of acquiring the component identification information and the operation of collecting component 91. Acquisition section 41 performs the process illustrated in step S13. Component supply device 12 performs the process illustrated in step S11.

Operation control section 42 performs the determination and the process illustrated in step S12, step S14, and step S15. Operation control section 42 causes acquisition section 41 to perform the process illustrated in step S13. Storage section 43 performs the process illustrated in step S16. The matters described in the present description can be selected and applied as appropriate. Further, the matters described in the present description can be combined as appropriate.

### 1-3-1. Acquisition Section 41

Acquisition section 41 acquires, for component 91 supplied to collection position PP1 of component supply device 12 that supplies component 91 to be mounted on board 90, the component identification information from identification member 70 having the component identification information capable of identifying component 91 (step S13 illustrated in FIG. 4). Acquisition section 41 may take various forms as long as the component identification information can be acquired from identification member 70.

Identification member 70 has various types of information on component 91. For example, identification member 70 can have information on at least one of the component identification information, a type, a vendor, and a lot of component 91. Acquisition section 41 can identify component 91 supplied from component supply device 12 by acquiring the component identification information of component 91 from identification member 70. Similarly, acquisition section 41 can acquire the above-described information on component 91 supplied from component supply device 12.

A known identification member can be used as identification member 70. For example, a one-dimensional code or a two-dimensional code can be used as identification member 70. When identification member 70 is a one-dimensional code or a two-dimensional code, acquisition section 41 can acquire various types of information such as the component identification information using a known code reader (a barcode reader capable of reading a barcode, an imaging device capable of reading a two-dimensional code, or the like). A wireless tag can also be used as identification member 70. When identification member 70 is a wireless tag, acquisition section 41 can acquire various types of information such as the component identification information using a known wireless device capable of wireless communication with the wireless tag.

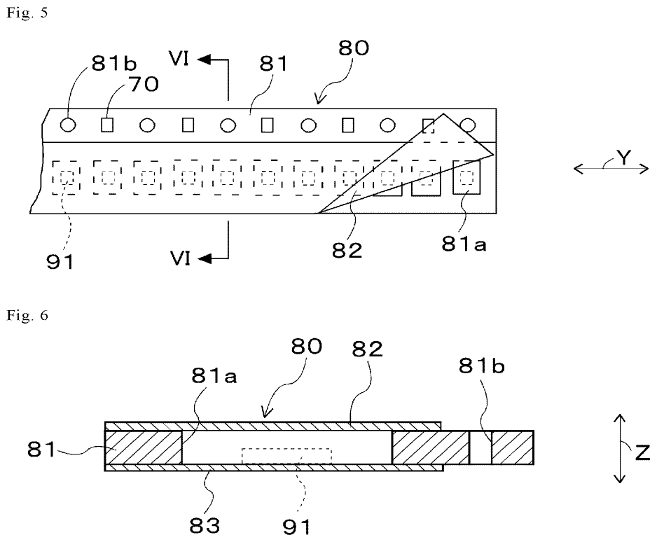

Component supply device 12 according to the embodiment is feeder 12a. Feeder 12a pitch-feeds carrier tape 80 in which components 91 are accommodated, and supplies component 91 so that component 91 can be collected at collection position PP1. As illustrated in FIGS. 5 and 6, for example, carrier tape 80 according to the embodiment includes base tape 81, cover tape 82, and bottom tape 83. Base tape 81 is a base portion of carrier tape 80, and is provided with multiple cavities 81a and multiple feed holes 81b.

Component 91 is accommodated in each of multiple cavities 81a. Multiple cavities 81a are provided at predetermined pitch intervals in the longitudinal direction of carrier tape 80 at the center portion in the width direction of base tape 81.

Multiple feed holes 81b are used when carrier tape 80 is conveyed in the conveyance direction (Y-axis direction in component mounter 10 illustrated in FIG. 1). Multiple feed holes 81b are provided at predetermined pitch intervals in the longitudinal direction of carrier tape 80 on the one end side in the width direction of base tape 81.

Cover tape 82 seals cavity 81a of base tape 81. Cover tape 82 is attached to the upper surfaces of both end portions of base tape 81 in the width direction with, for example, an adhesive. Bottom tape 83 is attached to the lower surface of base tape 81 with, for example, an adhesive, and prevents component 91 accommodated in cavity 81a from falling out. Carrier tape 80 may be an embossed tape, a paper tape, or the like in which base tape 81 and bottom tape 83 are integrally formed.

Identification member 70 can be provided at any position of base tape 81. For example, identification member 70 can be provided between feed holes 81b capable of the pitch-feed of carrier tape 80 or between cavities 81a in which components 91 are accommodated. In carrier tape 80 illustrated in FIG. 5, identification member 70 is provided between feed holes 81b. In this case, acquisition section 41 can acquire the component identification information from identification member 70 from which the component identification information can be acquired as carrier tape 80 is pitch-fed.

Specifically, in carrier tape 80 illustrated in FIG. 5, cavities 81a facing feed holes 81b in the width direction and cavities 81a facing identification member 70 in the width direction are alternately provided in the longitudinal direction. Therefore, as carrier tape 80 is pitch-fed, the two types of cavities 81a are alternately positioned at collection position PP1. When cavity 81a facing identification member 70 is positioned at collection position PP1, acquisition section 41 can acquire the component identification information from identification member 70. When cavity 81a facing feed hole 81b is positioned at collection position PP1, acquisition section 41 cannot acquire the component identification information. In this way, acquisition section 41 can acquire the component identification information from identification member 70 from which the component identification information can be acquired as carrier tape 80 is pitch-fed.

Acquisition section 41 can also acquire component identification information for each of a predetermined number of identification members 70. In the above example, acquisition section 41 can acquire the component identification information from identification member 70 each time cavity 81a facing identification member 70 is positioned at collection position PP1 a predetermined number of times. When identification member 70 is provided between cavities 81a, acquisition section 41 can acquire the component identification information from identification member 70 each time cavity 81a is positioned at collection position PP1 as carrier tape 80 is pitch-fed. In this case as well, acquisition section 41 can acquire the component identification information for each of the predetermined number of identification members 70.

Specifically, acquisition section 41 can acquire the component identification information from identification member 70 each time cavity 81a is positioned at collection position PP1 a predetermined number of times. In any of the above-described embodiments, acquisition section 41 can acquire various types of information such as the component identification information using the above-described reading device. For example, identification member 70 illustrated in FIG. 5 is a two-dimensional code. For example, acquisition section 41 can acquire various types of information such as the component identification information by reading the two-dimensional code using board camera 15.

### 1-3-2. Component Supply Device 12

When cavity 81a is positioned at collection position PP1 based on the pitch-feed of carrier tape 80, component mounter 10 performs the collection operation of collecting and holding component 91. As described above, cases in which component mounter 10 performs the collection operation include a case in which acquisition section 41 performs the operation of acquiring the component identification information and a case in which acquisition section 41 does not perform the operation of acquiring the component identification information. When performing the operation of acquiring the component identification information, acquisition section 41 needs to read the two-dimensional code using board camera 15, for example. Therefore, the operation of acquiring the component identification information by acquisition section 41 is performed after component 91 has reached collection position PP1.

However, even in a case where the operation of acquiring the component identification information is not performed, when the collection operation is started after component 91 has reached collection position PP1, the cycle time may increase. In this case, component mounter 10 can suppress the increase in the cycle time by starting the collection operation when component 91 is expected to reach collection position PP1. Therefore, component supply device 12 transmits first completion notification or second completion notification (step S11 illustrated in FIG. 4). The first completion notification notifies that component 91 is supplied to collection position PP1 for the operation of acquiring the component identification information by acquisition section 41. The second completion notification notifies that component 91 is supplied to collection position PP1 for the collection operation of collecting and holding component 91.

Specifically, the first completion notification is completion notification for notifying that component 91 has reached collection position PP1, and the second completion notification is expectation notification transmitted when component 91 is expected to reach collection position PP1. Here, the expectation notification includes notification after a predetermined time has elapsed since feeder 12a has pitch-fed carrier tape 80 in which components 91 are accommodated. The predetermined time is, for example, obtained by subtracting a time required for the notification from a time from the start of the pitch-feed of carrier tape 80 to the completion of the pitch-feed. Component mounter 10 may be configured to set in advance whether the completion notification (first completion notification) for notifying feeder 12a that component 91 has reached collection position PP1 or the expectation notification (second completion notification) transmitted when component 91 is expected to reach collection position PP1 is to be transmitted.

For example, feeder 12a includes a sprocket, a drive device that rotationally drives the sprocket, and a position detector that detects a rotational position of the sprocket. The sprocket pitch-feeds carrier tape 80. For example, as the drive device, a positioning-capable electric motor, such as a stepping motor or a servo motor, can be used. As the position detector, for example, an encoder or the like can be used. For example, component supply device 12 can recognize that component 91 has reached collection position PP1 by a detection value of the position detector, and can transmit the completion notification (first completion notification) after component 91 has actually reached collection position PP1.

In addition, component supply device 12 can recognize the time when component 91 is expected to reach collection position PP1, for example, based on a command to the drive device (the number of pulses of the pulse signals transmitted to the stepping motor or a position command transmitted to the servo motor) and the detection value of the position detector (current position). Therefore, component supply device 12 can transmit the expectation notification (second completion notification) before component 91 reaches collection position PP1.

When it is estimated that a time required for component 91 to reach collection position PP1 is equal to or less than a predetermined time, component supply device 12 can determine that component 91 is expected to reach collection position PP1. The predetermined time may be optionally set as long as the increase in the cycle time described above can be suppressed. For example, the predetermined time can be set to be equal to or less than a required time from when holding member 30 starts to be lowered until holding member 30 reaches component 91 and becomes able to collect component 91.

### 1-3-3. Operation Control Section 42

Operation control section 42 controls the operation of acquiring the component identification information by acquisition section 41 based on the first completion notification and the operation of collecting component 91 based on the second completion notification. Specifically, in a case where the operation of acquiring the component identification information is performed, when the first completion notification (the completion notification for notifying that component 91 has reached collection position PP1) is received from component supply device 12 (when Yes in step S12 illustrated in FIG. 4), operation control section 42 causes acquisition section 41 to perform the operation of acquiring the component identification information (step S13). Accordingly, acquisition section 41 can start the operation of acquiring the component identification information after component 91 has reached collection position PP1.

After the operation of acquiring the component identification information is performed, operation control section 42 lowers holding member 30 capable of collecting and holding component 91 and causes holding member 30 to collect component 91 (step S14). Specifically, operation control section 42 drives Z-axis motor 27 illustrated in FIG. 2 to move tool shaft 24 in contact with lever 29 and holding member 30 attached to the lower end portion of tool shaft 24 downward in the vertical direction (Z-axis direction). When holding member 30 reaches component 91, operation control section 42 causes holding member 30 to collect component 91.

In addition, in a case where the operation of acquiring the component identification information is not performed, when the second completion notification (the expectation notification transmitted when component 91 is expected to reach collection position PP1) is received from component supply device 12 (when No in step S12), operation control section 42 lowers holding member 30 and causes holding member 30 to collect component 91 (step S15). When the second completion notification (expectation notification) is received from component supply device 12, operation control section 42 can lower holding member 30 and cause holding member 30 to collect component 91 in the same manner as in the case described above. Accordingly, component mounter 10 can start the lowering of holding member 30 when component 91 is expected to reach collection position PP1, and can suppress the increase in the cycle time as compared with a case where the lowering of holding member 30 is started after component 91 has reached collection position PP1.

As described above, the operation of acquiring the component identification information can be performed at any timing, for example, at every predetermined number of identification members 70. The timing at which the operation of acquiring the component identification information is performed can be determined in advance between component supply device 12 and control device 16. For example, the timing at which the operation of acquiring the component identification information is performed can be included in the component supply command transmitted from control device 16 to component supply device 12.

### 1-3-4. Storage Section 43

Storage section 43 stores the component identification information of component 91 acquired by acquisition section 41 and the board identification information capable of identifying board 90 on which component 91 is mounted in storage device 60 in association with each other (step S16 illustrated in FIG. 4). Storage device 60 need only store the component identification information and the board identification information in association with each other, and a known storage device (database) can be used. Storage device 60 can also be formed on a cloud. For example, storage device 60 according to the embodiment is provided in a storage device (database) of a management device that manages component mounter 10. Accordingly, the worker or the production management device can track and investigate components 91 supplied from component supply device 12.

Storage section 43 can also store the component identification information of component 91 acquired by acquisition section 41, the board identification information capable of identifying board 90 on which component 91 is mounted, and the mounting position information capable of specifying the mounting position on board 90 on which component 91 is mounted in storage device 60 in association with each other. When component 91 supplied from component supply device 12 is discarded without being mounted on board 90, storage section 43 can store the component identification information of component 91 acquired by acquisition section 41 and discard information indicating that component 91 has been discarded in storage device 60 in association with each other.

Storage section 43 can also store, in storage device 60, component supply device information capable of specifying component supply device 12 that has supplied component 91, component mounter information capable of specifying component mounter 10 equipped with component supply device 12 that has supplied component 91, and the like. In addition, storage section 43 can also store date and time information capable of specifying a date and time when component 91 is supplied, worker information capable of specifying a worker who prepares component supply device 12, environmental information capable of specifying an ambient temperature and humidity of a production facility when component 91 is supplied, and the like in storage device 60.

As described above, components 91 supplied from component supply device 12 include component 91 of which the component identification information is not acquired by acquisition section 41. Therefore, storage section 43 can complement the component identification information of component 91 of which the component identification information is not acquired by acquisition section 41 based on the relative order for component 91 of which the component identification information is acquired by acquisition section 41, and store the complemented component identification information in storage device 60.

For example, in carrier tape 80 illustrated in FIG. 5, when cavity 81a facing identification member 70 is positioned at collection position PP1, acquisition section 41 can acquire the component identification information from identification member 70. In addition, when cavity 81a facing feed hole 81b is positioned at collection position PP1, acquisition section 41 cannot acquire the component identification information. In this case, storage section 43 can complement the component identification information of component 91 accommodated in cavity 81a facing feed hole 81b based on the relative order for component 91 accommodated in cavity 81a facing identification member 70.

For example, it is assumed that the component identification information of component 91 accommodated in cavity 81a facing identification member 70 and acquired by acquisition section 41 is represented by information AAA0001. Information AAA0001 includes symbol portion AAA and numeric portion 0001. The component identification information of component 91 which is accommodated in cavity 81a positioned at collection position PP1 next to cavity 81a and of which component identification information is not acquired by acquisition section 41 can be represented by, for example, information AAA00011.

Information AAA00011 includes symbol portion AAA, numeric portion 0001, and relative order portion 1. Relative order portion 1 indicates a relative order (in this case, the first) for component 91 of which component identification information is acquired by acquisition section 41 (in this case, component 91 of which the component identification information is represented by information AAA0001). As described above, when component supply device 12 is feeder 12a, the relative order indicates an accommodation order of components 91 in carrier tape 80 starting from component 91 of which the component identification information is acquired by acquisition section 41.

Next, the component identification information of component 91 which is accommodated in cavity 81a positioned at collection position PP1 and of which the component identification information is acquired by acquisition section 41 is represented by information AAA0002. Information AAA0002 includes symbol portion AAA and numeric portion 0002. In numeric portion 0002, 1 is added to numeric portion 0001 of the component identification information of component 91 which is previously acquired by acquisition section 41. As described above, when component supply device 12 is feeder 12a, the numeric portion of the component identification information indicates the accommodation order, in carrier tape 80, of components 91 of which the component identification information is acquired by acquisition section 41.

Next, the component identification information of component 91 which is accommodated in cavity 81a positioned at collection position PP1 and of which the component identification information is not acquired by acquisition section 41 is represented by information AAA00021. Information AAA00021 includes symbol portion AAA, numeric portion 0002, and relative order portion 1. Relative order portion 1 indicates a relative order (in this case, the first) for component 91 of which component identification information is acquired by acquisition section 41 (in this case, component 91 of which the component identification information is represented by information AAA0002). Storage section 43 can acquire the component identification information and complement the component identification information in the same manner for subsequent components 91. Symbol portion AAA indicates various types of information on component 91.

In this way, storage section 43 can store the component identification information of component 91 acquired by acquisition section 41 or the complemented component identification information of component 91 and the board identification information capable of identifying board 90 on which component 91 is mounted in storage device 60 in association with each other. Storage section 43 can also store the component identification information of component 91 acquired by acquisition section 41 or the complemented component identification information of component 91, the board identification information capable of identifying board 90 on which component 91 is mounted, and the mounting position information capable of specifying the mounting position on board 90 on which component 91 is mounted in storage device 60 in association with each other.

Further, when component 91 supplied from component supply device 12 is discarded without being mounted on board 90, storage section 43 can store the component identification information of component 91 acquired by acquisition section 41 or the complemented component identification information of component 91 and the discard information indicating that component 91 has been discarded in storage device 60 in association with each other.

### 2. Others

Component mounter 10 can also determine whether component 91 supplied from component supply device 12 is appropriate based on the component identification information of component 91 acquired by acquisition section 41. Component mounter 10 can also determine whether the supply state of component 91 supplied from component supply device 12 is good. For example, component mounter 10 captures the image of component 91 supplied from component supply device 12 using board camera 15. Component mounter 10 can determine whether the supply state of component 91 is good by performing the image processing on the image data of component 91 supplied from component supply device 12. In these cases, storage section 43 can store the supply information indicating whether component 91 is appropriate and whether the supply state of component 91 is good, in storage device 60 together with the component identification information and the like.

### 3. Control Method

The foregoing description regarding the component mounter 10 applies equally to the control method. Specifically, the control method includes an acquisition step, a notification step, and an operation control step. The acquisition step corresponds to control performed by acquisition section 41. The notification step corresponds to control performed by component supply device 12. The operation control step corresponds to control performed by operation control section 42. The control method can further include a storage step. The storage step corresponds to control performed by storage section 43.

### 4. Example of Effect

With component mounter 10, it is possible to appropriately control the operation of acquiring the component identification information and the operation of collecting component 91. The foregoing description regarding the component mounter 10 applies equally to the control method.

### REFERENCE SIGNS LIST

10: component mounter, 12: component supply device, 12a: feeder, 30: holding member, 41: acquisition section, 42: operation control section, 43: storage section, 60: storage device, 70: identification member, 80: carrier tape, 81a: cavity, 81b: feed hole, 90: board, 91: component, PP1: collection position.

1. A component mounter comprising:
an acquisition section configured to acquire, for a component supplied to a collection position of a component supply device configured to supply the component to be mounted on a board, component identification information from an identification member having the component identification information capable of identifying the component;
the component supply device configured to transmit a first completion notification for notifying that the component has been supplied to the collection position for an operation of acquiring the component identification information by the acquisition section, or a second completion notification for notifying that the component has been supplied to the collection position for a collection operation of collecting and holding the component; and
an operation control section configured to control the operation of acquiring the component identification information by the acquisition section based on the first completion notification and the operation of collecting the component based on the second completion notification.

2. The component mounter according to claim 1,
wherein the first completion notification is completion notification for notifying that the component has reached the collection position, and
the second completion notification is expectation notification transmitted when the component is expected to reach the collection position.

3. The component mounter according to claim 2, wherein the component supply device is configured to determine that the component is expected to reach the collection position when it is estimated that a time required for the component to reach the collection position is equal to or less than a predetermined time.

4. The component mounter according to claim 1,
wherein the operation control section is configured to, in a case where the operation of acquiring the component identification information is performed, when the first completion notification is received from the component supply device, cause the acquisition section to perform the operation of acquiring the component identification information and lower a holding member capable of collecting and holding the component and cause the holding member to collect the component after the acquisition operation is performed, and to, in a case where the operation of acquiring the component identification information is not performed, when the second completion notification is received from the component supply device, lower the holding member and cause the holding member to collect the component.

5. The component mounter according to claim 1, wherein the identification member has information on at least one of the component identification information, a type, a vendor, and a lot of the component.

6. The component mounter according to claim 1, wherein the identification member is a one-dimensional code or a two-dimensional code.

7. The component mounter according to claim 1, wherein the identification member is a wireless tag.

8. The component mounter according to claim 1, further comprising:
a storage section configured to store the component identification information of the component acquired by the acquisition section and board identification information capable of identifying the board on which the component is mounted, in a storage device in association with each other.

9. The component mounter according to claim 1,
wherein the component supply device is a feeder configured to pitch-feed a carrier tape in which the components are accommodated and supply the component so that the component is collectable at the collection position, and
the identification member is provided between feed holes capable of the pitch-feed of the carrier tape or between cavities in which the components are accommodated.

10. The component mounter according to claim 9,
wherein the identification member is provided between the feed holes, and
the acquisition section is configured to acquire the component identification information from the identification member from which the component identification information is acquirable as the carrier tape is pitch-fed.

11. The component mounter according to claim 9, wherein the acquisition section is configured to acquire the component identification information for each of a predetermined number of the identification members.

12. A control method comprising:
an acquisition step of acquiring, for a component supplied to a collection position of a component supply device configured to supply the component to be mounted on a board, component identification information from an identification member having the component identification information capable of identifying the component;
a notification step of transmitting a first completion notification for notifying that the component has been supplied to the collection position for an operation of acquiring the component identification information by the acquisition step or a second completion notification for notifying that the component has been supplied to the collection position for a collection operation of collecting and holding the component; and
an operation control step of controlling the operation of acquiring the component identification information by the acquisition step based on the first completion notification and the operation of collecting the component based on the second completion notification.
